(19) United States
(12) Patent Application Publication
(10) Pub. No.: US 2006/0175688 A1
(43) Pub. Date: Aug. 10, 2006

(54) STACKED INTEGRATED CIRCUIT PACKAGE SYSTEM

(75) Inventor: JungHwan Jang, Singapore (SG)

Correspondence Address: THE LAW OFFICES OF MIKIO ISHIMARU, 333 W. EL CAMINO REAL, SUITE 330, SUNNYVALE, CA, 94087, US

(73) Assignee: STATS CHIPPAC LTD., Singapore (SG)

(21) Appl. No.: 11/163,556

(22) Filed: Oct. 22, 2005

Related U.S. Application Data
(60) Provisional application No. 60/650,056, filed on Feb. 4, 2005.

(51) Int. Cl. H01L 23/495

(52) U.S. Cl. 257/666; 257/686

(57) ABSTRACT

An integrated circuit package system having stacked lead frames including providing a first stackable lead frame package having a first integrated circuit therein and a second stackable lead frame package with a second integrated circuit therein. The first stackable lead frame package having a plurality of leads including protrusions is mounted to the second stackable lead frame package having a second plurality of leads including protrusions.

### CROSS-REFERENCE TO RELATED APPLICATION(S)

This application claims the benefit of U.S. Provisional Patent Application Ser. No. 60/650,056 filed Feb. 4, 2005, and the subject matter thereof is hereby incorporated herein by reference thereto.

### TECHNICAL FIELD

The present invention relates generally to integrated circuit package systems, and more particularly to a system for integrated circuit package system having stacked packages.

### BACKGROUND ART

In order to interface an integrated circuit with other circuitry, it is common to mount it on a lead frame or substrate. Each integrated circuit has bonding pads that are individually connected to the lead frame's lead finger pads using extremely fine gold or aluminum wires. The assemblies are then packaged by individually encapsulating them in molded plastic or ceramic bodies to create an integrated circuit package.

Integrated circuit packaging technology has seen an increase in the number of integrated circuits mounted on a single circuit board or substrate. The new packaging designs are more compact in form factors, such as the physical size and shape of an integrated circuit, and providing a significant increase in overall integrated circuit density. However, integrated circuit density continues to be limited by the “real estate” available for mounting individual integrated circuits on a substrate. Even larger form factor systems, such as PC's, compute servers, and storage servers, need more integrated circuits in the same or smaller “real estate”. Particularly acute, the needs for portable personal electronics, such as cell phones, digital cameras, music players, PDA's, and location-based devices, have further driven the need for integrated circuit density.

This increased integrated circuit density, has led to the development of multi-chip packages in which more than one integrated circuit can be packaged. Each package provides mechanical support for the individual integrated circuits and one or more layers of interconnect lines that enable the integrated circuits to be connected electrically to surrounding circuitry. Current multi-chip packages, also commonly referred to as multi-chip modules, typically consist of a PCB substrate onto which a set of separate integrated circuit components is directly attached. Such multi-chip packages have been found to increase integrated circuit density and miniaturization, improve signal propagation speed, reduce overall integrated circuit size and weight, improve performance, and lower costs—all primary goals of the computer industry.

Multi-chip packages whether vertically or horizontally arranged, can also present problems because they usually must be pre-assembled before the integrated circuit and integrated circuit connections can be tested. Thus, when integrated circuits are mounted and connected in a multi-chip module, individual integrated circuits and connections cannot be tested individually, and it is not possible to identify known-good-die (“KGD”) before being assembled into larger circuits. Consequently, conventional multi-chip packages lead to assembly process yield problems. This fabrication process, which does not identify KGD, is therefore less reliable and more prone to assembly defects.

Moreover, vertically stacked integrated circuits in typical multi-chip packages can present problems beyond those of horizontally arranged integrated circuit packages, further complicating the manufacturing process. It is more difficult to test and thus determine the actual failure mode of the individual integrated circuits. Moreover the substrate and integrated circuit are often damaged during assembly or testing, complicating the manufacturing process and increasing costs. The vertically stacked integrated circuit problems can be greater than the benefits.

Thus, a need still remains for improved packaging methods, systems, and designs. In view of the ever-increasing need to save costs and improve efficiencies, it is more and more critical that answers be found to these problems.

### DISCLOSURE OF THE INVENTION

The present invention provides an integrated circuit package system having stacked lead frames providing lead frame packages having integrated circuits. One lead frame including a plurality of leads having protrusions is mounted vertically to another lead frame including a plurality of leads having protrusions.

Certain embodiments of the invention have other advantages in addition to or in place of those mentioned or obvious from the above. The advantages will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit package system having stacked lead frames in an embodiment of the present invention;

FIG. 2A is a top plan view of the first lead frame shown in FIG. 1;

FIG. 2B is a top plan view of the second lead frame shown in FIG. 1;

FIG. 3A is a cross-sectional view of the first lead frame shown in FIG. 1 and FIG. 2A;

FIG. 3B is a cross-sectional view of the second lead frame shown in FIG. 1 and FIG. 2B;

FIG. 4A is a cross-sectional view of the first lead frame in an alternate embodiment of the present invention;

FIG. 4B is a cross-sectional view of the second lead frame in an alternate embodiment of the present invention;

FIG. 5A is a package preparation phase of the assembly process for the first stackable lead frame package of the integrated circuit package system;

FIG. 5B is a package preparation phase of the assembly process for the second stackable lead frame package of the integrated circuit package system;

FIG. 6A is an integrated circuit attachment phase of the assembly process for the first stackable lead frame package of the integrated circuit package system;

FIG. 6B is a an integrated circuit attachment phase of the assembly process for the second stackable lead frame package of the integrated circuit package system;

FIG. 7A is an electrical connection phase of the assembly process for the first stackable lead frame package of the integrated circuit package system;

FIG. 7B is an electrical connection phase of the assembly process for the second stackable lead frame package of the integrated circuit package system;

FIG. 8A is a package formation phase of the assembly process for the first stackable lead frame package of the integrated circuit package system;

FIG. 8B is a package formation phase of the assembly process for the second stackable lead frame package of the integrated circuit package system;

FIG. 9 is a mounting phase of the assembly process for the integrated circuit package system having stacked lead frames; and

FIG. 10 is a flow chart of a package system for the integrated circuit package system having stacked lead frames.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known package designs, manufacturing specifications, and process steps are not disclosed in detail. Likewise, the drawings showing embodiments of the integrated circuit package system having stacked lead frames are semi-diagrammatic and not to scale and, particularly, some of the dimensions are for the clarity of presentation and are shown exaggerated in the figures. Similarly, although the cross-section views in the drawings for ease of description show upper/top and lower/bottom orientations, this arrangement in the figures is arbitrary and is not intended to suggest that the packages necessarily be in the positions in the drawing. Generally, the device can be operated in any orientation. The same numbers are used in all the drawing figures to relate to the same elements.

The term “horizontal” as used herein is defined as a plane parallel to the conventional plane or surface of the package, regardless of its orientation. The term “vertical” refers to a direction perpendicular to the horizontal as just defined. Terms, such as “on”, “above”, “below”, “bottom”, “top”, “side”(as in “sidewall”), “higher”, “lower”, “upper”, “over”, and “under”, are defined with respect to the horizontal plane.

Referring now to FIG. 1, therein is shown a cross-sectional view of a stacked integrated circuit package system 100 in an embodiment of the present invention. The integrated circuit package system 100 having stacked lead frames includes a first stackable lead frame package 102 mounted vertically to a second stackable lead frame package 104. The first stackable lead frame package 102 includes a first lead frame 106 having a first plurality of leads 110 and a first die paddle 118. Similarly, the second stackable lead frame package 104 includes a second lead frame 108 having a second plurality of leads 112 and a second die paddle 120.

The first plurality of leads 110 includes a first plurality of protrusions 114, designed for connection of the first stackable lead frame package 102 and the second stackable lead frame package 104. Similarly, the second plurality of leads 112 includes a second plurality of protrusions 116, designed for connection of the first stackable lead frame package 102 and the second stackable lead frame package 104. The first plurality of protrusions 114 are perpendicular to the first plurality of leads 110 and designed for mechanical and electrical connection of the first stackable lead frame package 102 and the second stackable lead frame package 104. Similarly, the second plurality of protrusions 116 are perpendicular to the second plurality of leads 112 and designed for mechanical and electrical connection of the first stackable lead frame package 102 and the second stackable lead frame package 104.

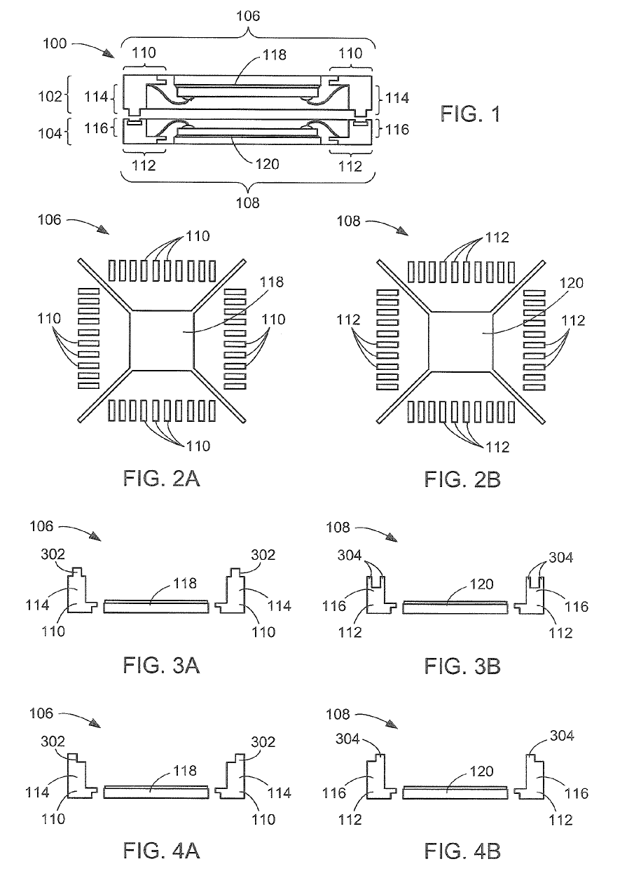

Referring now to FIG. 2A, therein is shown a top plan view of the first lead frame 106 shown in FIG. 1. Further, the first lead frame 106 is shown before any attachments, mountings or connections. The first lead frame 106 is shown including each of the first plurality of leads 110 and the first die paddle 118.

For illustrative purposes, the first lead frame 106 is shown having each of the first plurality of leads 110 and the first die paddle 118, although it is to be understood that the first plurality of leads 110 and the first die paddle 118 may differ in number, position, configuration and dimension, as well. In addition, it is to be understood that the first lead frame 106 may include other elements that may be necessary or desired.

Referring now to FIG. 2B, therein is shown a top plan view of the second lead frame 108 shown in FIG. 1. Further, the second lead frame 108 is shown before any attachments, mountings or connections. The second lead frame 108 is shown including each of the second plurality of leads 112 and the second die paddle 120.

For illustrative purposes, the second lead frame 108 is shown having each of the second plurality of leads 112 and the second die paddle 120, although it is to be understood that the second plurality of leads 112 and the second die paddle 120 may differ in number, position, configuration and dimension, as well. In addition, it is to be understood that the second lead frame 108 may include other elements that may be necessary or desired.

Referring now to FIG. 3A, therein is shown a cross-sectional view of the first lead frame 106 shown in FIG. 1 and FIG. 2A. The first lead frame 106 is shown before any attachments, mountings or connections, as in the plan view of FIG. 2A. The first plurality of leads 110 includes the first plurality of protrusions 114 with a first plurality of extensions 302, designed for connecting the first lead frame 106 with the second lead frame 108. The first plurality of leads 110, the first plurality of protrusions 114 and the first plurality of extensions 302 are mechanically and electrically integrated.

Referring now to FIG. 3B, therein is shown a cross-sectional view the second lead frame 108 shown in FIG. 1 and FIG. 2B. The second lead frame 108 is shown before any attachments, mountings or connections, as in the plan view of FIG. 2B. The second plurality of leads 112 includes the second plurality of protrusions 116 having a second plurality of extensions 304, designed for connecting the first lead frame 106 with the second lead frame 108. The second plurality of leads 112, the second plurality of protrusions 116 and the second plurality of extensions 304 are mechanically and electrically integrated.

For illustrative purposes, the first plurality of extensions 302 and the second plurality of extensions 304 are shown as complementary to one another and interlocking one into the other, although it is to be understood the first plurality of extensions 302 and the second plurality of extensions 304 need not be complimentary to one another and need not interlock one into the other.

Referring now to FIG. 4A, therein is shown a cross-sectional view of the first lead frame 106 in an alternate embodiment of the present invention The first plurality of protrusions 114 is shown with the first plurality of extensions 302 offset rather than symmetrical as in FIG. 1, FIG. 2A and FIG. 3A.

Referring now to FIG. 4B, therein is shown a cross-sectional view of the second lead frame 108 in an alternate embodiment of the present invention The second plurality of protrusions 116 is shown with the second plurality of extensions 304 offset rather than symmetrical as in FIG. 1, FIG. 2B and FIG. 3B.

For illustrative purposes, first plurality of extensions 302 is shown with the second plurality of extensions 304 complimentary to one another and interlocking one into the other, although it is to be understood that the first plurality of extensions and the second plurality of extensions 304 need not be complimentary to one another and need not interlock one into the other.

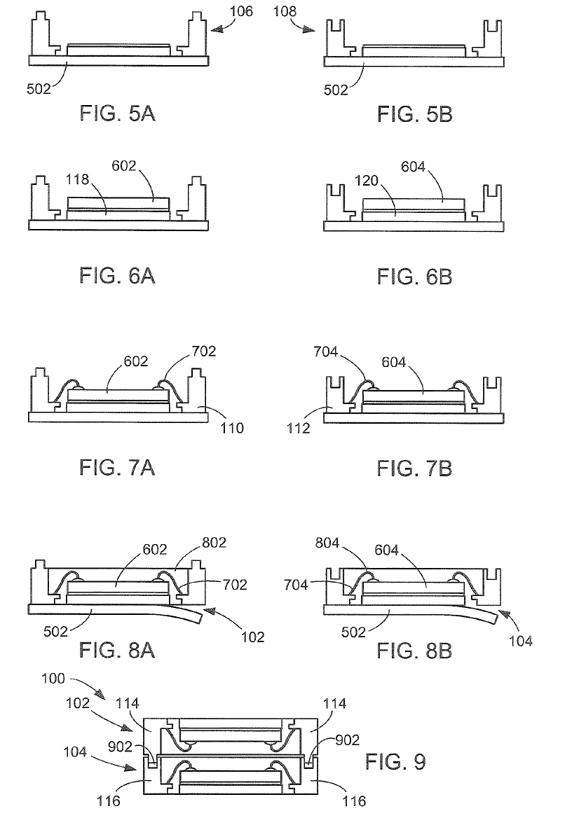

Referring now to FIG. 5A, therein is shown a package preparation phase of the assembly process for the first stackable lead frame package 102 of the integrated circuit package system 100. A coverlay tape 502 is attached to the bottom of the first lead frame 106. For illustrative purposes, the coverlay tape 502 is shown, although it is to be understood that other materials or attachment processes may be used, as well.

Referring now to FIG. 5B, therein is shown a package preparation phase of the assembly process for the second stackable lead frame package 104 of the integrated circuit package system 100. Similarly, the coverlay tape 502 is attached to the bottom of the second lead frame 108. For illustrative purposes, the coverlay tape 502 is shown, although it is to be understood that other materials or attachment processes may be used, as well.

Referring now to FIG. 6A, therein is shown an integrated circuit attachment phase of the assembly process for the first stackable lead frame package 102 of the integrated circuit package system 100. A first integrated circuit 602 attaches to the top of the first die paddle 118.

Referring now to FIG. 6B, therein is shown an integrated circuit attachment phase of the assembly process for the second stackable lead frame package 104 of the integrated circuit package system 100. A second integrated circuit 604 attaches to the top of the second die paddle 120.

Referring now to FIG. 7A, therein is shown an electrical connection phase of the assembly process for the first stackable lead frame package 102 of the integrated circuit package system 100. A first plurality of bond wires 702 electrically connects the first integrated circuit 602 to the first plurality of leads 110. For illustrative purposes, the first plurality of bond wires 702 is shown as conductive wires, although it is to be understood that other materials or connection processes may be used, as well.

Referring now to FIG. 7B, therein is shown an electrical connection phase of the assembly process for the second stackable lead frame package 104 of the integrated circuit package system 100. A second plurality of bond wires 704 electrically connects the second integrated circuit 604 to the second plurality of leads 112. For illustrative purposes, the second plurality of bond wires 704 is shown as conductive wires, although it is to be understood that other materials or connection processes may be used, as well.

Referring now to FIG. 8A, therein is shown a package formation phase of the assembly process for the first stackable lead frame package 102 of the integrated circuit package system 100. An encapsulant 802, such as a molding compound, plastic, or polymer, may be used to mold the first lead frame 106, the first integrated circuit 602 and the first plurality of leads 110 to form the first stackable lead frame package 102. After molding, the coverlay tape 502 is removed from the bottom of the first stackable lead frame package 102.

Referring now to FIG. 8B, therein is shown a package formation phase of the assembly process for the second stackable lead frame package 104 of the integrated circuit package system 100. The encapsulant 804, such as a molding compound, plastic, or polymer, may be used to mold the second lead frame 108, the second integrated circuit 604 and the second plurality of leads 112 to form the second stackable lead frame package 104. After molding, the coverlay tape 502 is removed from the bottom of the second stackable lead frame package 104.

Referring now to FIG. 9, therein is shown a mounting phase of the assembly process for the stacked integrated circuit package system 100. The first stackable lead frame package 102 mounts vertically to the second stackable lead frame package 104 whereby the first plurality of protrusions 114 is designed to mate with the second plurality of protrusions 116. A conductive epoxy 902 may be used to secure the connection between the first plurality of protrusions 114 and the second plurality of protrusions 116. For illustrative purposes, the conductive epoxy 902 may be used to secure the connection, although it is to be understood that other materials or connection processes may be used, as well.

The first stackable lead frame package 102 and the second stackable lead frame package 104 can be tested individually prior to assembling the first stackable lead frame package 102 to the second stackable lead frame package 104 to assure that each package is properly formed and include functioning integrated circuits prior to assembly. The first stackable lead frame package 102 and the second stackable lead frame package 104 can be tested prior to assembly thereby substantially improving the assembly process yields during fabrication of the integrated circuit package system 100 having stacked lead frames. The assembly of the first stackable lead frame package 102 and the second stackable lead frame package 104 includes mounting vertically one above another and electrically connecting the first plurality of protrusions 114 and the second plurality of protrusions 116 without the need for wire bonding or molding, thereby substantially improving the assembly process yield during fabrication of the integrated circuit package system 100 having stacked lead frames.

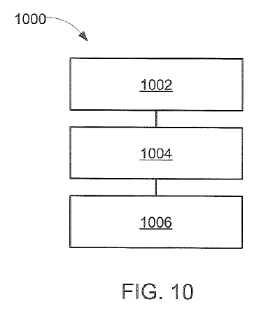

Referring now to FIG. 10, therein is shown a flow chart of a stacked integrated circuit package system 1000 for the integrated circuit package system 100. The flow chart of the system 1000 includes providing the first stackable lead frame package having the first integrated circuit therein, the first stackable lead frame package having the first plurality of leads including the first plurality of protrusions therein, in a block 1002; providing the second stackable lead frame package having the second integrated circuit therein, the second stackable lead frame package having the second plurality of leads including the second plurality of protrusions therein, in a block 1004; and mounting the first stackable lead frame package to the second stackable lead frame package mating the first plurality of protrusions and the second plurality of protrusions in a block 1006.

In greater detail, a method to fabricate the integrated circuit package system 100 having stacked lead frames, according to an embodiment of the present invention, is performed as follows:
(1) 1. The first plurality of leads 110 having the first plurality of protrusions 114 and the first die paddle 118 form the first lead frame 106. Similarly, the second plurality of leads 112 having the second plurality of protrusions 116 and the second die paddle 120 form the second lead frame 108. (FIG. 1)
(2) 2. The first integrated circuit 602 mechanically attaches to the first die paddle 118 and electrically connects with the first plurality of bond wires 702. Similarly, the second integrated circuit 604 mechanically attaches to the second die paddle 120 and electrically connects with the second plurality of bond wires 704. (FIG. 6A, 6B, 7A, 7B)
(3) 3. The first stackable lead frame package 102 including the first lead frame 106 and the first integrated circuit 602 is molded with the encapsulant 802. Similarly the second stackable lead frame package 104 including the second lead frame 108 and the second integrated circuit 604 is molded with the encapsulant 802. (FIG. 8A, 8B)
(4) 4. The integrated circuit package system 100 having stacked lead frames includes the first stackable lead frame package 102 mounted vertically to the second stackable lead frame package 104. The stacked packages including the first stackable lead frame package 102 and the second stackable lead frame package 104 are connected at the first plurality of protrusions 114 of the first plurality of leads 110 and the second plurality of protrusions 116 of the second plurality of leads 112 with the conductive epoxy 902. (FIG. 9)

An advantage is that the present invention improves the mounting and connection process between one lead frame package and another lead frame package. The modified lead frame and stacking improve the mounting process. This eliminates wire bonding and molding between package and package. Only a mounting process is required.

It has been discovered that the disclosed structure results in the simplification of the manufacturing process for the packages. The simplified manufacturing process has avoided the mold chase from the molding process. The mold chase does not affect integrated circuit, lead frame, package or PCB performance or reliability and hence has no effect on the final product or system.

It has also been discovered in the present invention that testability is improved. The several integrated circuits and packages can be fully tested prior to assembling them together into the package. This can virtually eliminate the risk of combining a good component with a bad component in the final assembled package.

Yet another discovery of the present invention is higher yield. A higher percentage of integrated circuit packages will meet product specifications through lower risk interconnection and molding processes as well as ensuring good components.

Again yet another discovery is the cost reduction provided by the present invention. Significant cost reduction is afforded by the higher yield, lower material usage and reduced equipment. Recurring costs are associated with wire bonding, molding, mold chases, and scrap.

Yet another important discovery of the present invention is that it valuably supports and services the historical trend of reducing costs, simplifying systems, and increasing performance. These and other valuable aspects of the present invention consequently further the state of the technology to at least the next level.

Thus, it has been discovered that the integrated circuit package system 100 having stacked lead frames of the present invention furnishes important and heretofore unavailable solutions, capabilities, and functional advantages. KGD and assembly process yield issues are effectively removed. Different integrated circuit and package connection interfaces, whether flip-chip, leaded, or other, are readily accommodated. The resulting process and configurations are straightforward, economical, uncomplicated, highly versatile and effective, and fully compatible with conventional manufacturing processes and technologies.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. A stacked integrated circuit package system comprising:
providing a first stackable lead frame package having a first integrated circuit therein, the first stackable lead frame package having a first plurality of leads including a first plurality of protrusions therein;
providing a second stackable lead frame package having a second integrated circuit therein, the second stackable lead frame package having a second plurality of leads including a second plurality of protrusions therein; and
mounting the first stackable lead frame package and the second stackable lead frame package.

2. The system as claimed in claim 1 wherein mounting the first stackable lead frame package to the second stackable lead frame package comprises mating the first plurality of protrusions to the second plurality of protrusions.

3. The system as claimed in claim 1 wherein mounting the first stackable lead frame package to the second stackable lead frame package comprises a first plurality of extensions of the first plurality of protrusions complimentary and mating to a second plurality of extensions of the second plurality of protrusions.

4. The system as claimed in claim 1 wherein mounting the first stackable lead frame package to the second stackable lead frame package comprises applying an epoxy to secure the first stackable lead frame package to the second stackable lead frame package.

5. The system as claimed in claim 1 further comprising forming electrical connections between the first stackable lead frame package and the second stackable lead frame package.

6. A stacked integrated circuit package system comprising:
providing a first lead frame having a first plurality of leads including a first plurality of protrusions;
mounting a first integrated circuit on the first lead frame;
encapsulating the first lead frame and the first integrated circuit forming a first stackable lead frame package;
providing a second lead frame having a second plurality of leads including a second plurality of protrusions;
mounting a second integrated circuit on the second lead frame;
encapsulating the second lead frame and the second integrated circuit forming a second stackable lead frame package; and
mounting the first stackable lead frame package and second stackable lead frame package.

7. The system as claimed in claim 6 wherein mounting the first stackable lead frame package to the second stackable lead frame package comprises mating the first plurality of protrusions and the second plurality of protrusions.

8. The system as claimed in claim 6 wherein mounting the first stackable lead frame package to the second stackable lead frame package comprises a first plurality of extensions of the first plurality of protrusions complimentary and mating to a second plurality of extensions of the second plurality of protrusions.

9. The system as claimed in claim 6 wherein mounting the first stackable lead frame package to the second stackable lead frame package comprises applying an epoxy to secure the first stackable lead frame package to the second stackable lead frame package.

10. The system as claimed in claim 6 further comprising forming electrical connections between the first stackable lead frame package and second stackable lead frame packages.

11. A stacked integrated circuit package system comprising:
a first stackable lead frame package having a first integrated circuit therein, the first stackable lead frame package having a first plurality of leads including a first plurality of protrusions therein; and
a second stackable lead frame package having a second integrated circuit therein, the second stackable lead frame package having a second plurality of leads including a second plurality of protrusions therein, and wherein the first stackable lead frame package is mounted to the second stackable lead frame package.

12. The system as claimed in claim 11 wherein the first stackable lead frame package is mounted to the second stackable lead frame package mating the first plurality of protrusions to the second plurality of protrusions.

13. The system as claimed in claim 11 wherein the first stackable lead frame package is mounted to the second stackable lead frame package comprises a first plurality of extensions of the first plurality of protrusions complimentary and mated to a second plurality of extensions of the second plurality of protrusions.

14. The system as claimed in claim 11 wherein the first stackable lead frame package mounted to the second stackable lead frame package comprises an epoxy applied to secure the first stackable lead frame package to the second stackable lead frame package.

15. The system as claimed in claim 11 wherein the first plurality of protrusions and the second plurality of protrusions electrically connect the first stackable lead frame package to the second stackable lead frame package.

16. A stacked integrated circuit package system comprising:
a first stackable lead frame package, encapsulated, comprising having a first lead frame having a first plurality of leads including a first plurality of protrusions, the first stackable lead frame package further comprising a first integrated circuit;
a second stackable lead frame package, encapsulated, comprising having a second lead frame having a second plurality of leads including a second plurality of protrusions, the second stackable lead frame package further comprising a second integrated circuit; and
the first stackable lead frame package mounted to the second stackable lead frame package mating the first plurality of protrusions to the second plurality of protrusions.

17. The system as claimed in claim 16 wherein the first stackable lead frame package is mounted to the second stackable lead frame package comprises a first plurality of extensions of the first plurality of protrusions complimentary and mated to a second plurality of extensions of the second plurality of protrusions.

18. The system as claimed in claim 16 wherein the first stackable lead frame package mounted to the second stackable lead frame package comprises an epoxy applied to secure the first stackable lead frame package to the second stackable lead frame package.

19. The system as claimed in claim 16 wherein mating the first plurality of protrusions to the second plurality of protrusions comprises a conductive epoxy.

20. The system as claimed in claim 16 wherein the first plurality of protrusions and the second plurality of protrusions electrically connect the first stackable lead frame package to the second stackable lead frame package.
